(19) United States
(12) Patent Application Publication
(10) Pub. No.: US 2026/0305092 A1
(43) Pub. Date: Oct. 1, 2026

(54) DISPLAY MODULE AND PREPARATION METHOD THEREFOR, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Biao LI, Beijing (CN); Zhihao XIE, Beijing (CN); Fan LI, Beijing (CN); Yangyang CAI, Beijing (CN); Jianli YAO, Beijing (CN); Wucheng YANG, Beijing (CN)

(21) Appl. No.: 19/479,362

(22) PCT Filed: Jan. 15, 2025
(86) PCT No.: PCT/CN2025/072529

§ 371 Date: Oct. 28, 2025

(30) Foreign Application Priority Data
Jan. 24, 2024 (CN) 202410102841.7

(51) Int. Cl. H10K 59/131; H05K 1/189; H10K 59/12; H10K 59/80; H10K 77/10

(52) U.S. Cl. CPC H10K 59/131; H05K 1/189; H10K 59/1201; H10K 59/8794; H10K 77/111; H05K 2201/10128

(57) ABSTRACT

A display module includes a display substrate including a display area and a first bonding area and a second bonding area sequentially disposed on one side of the display area, wherein a bonding pad is disposed on the second bonding area; an integrated circuit chip bonded to the first bonding area, wherein the integrated circuit chip includes a first side edge on a side close to the bonding pad; a flexible circuit board bonded to the bonding pad of the second bonding area and covering the bonding pad, wherein through holes are formed in the flexible circuit board, and the through holes expose at least part of the first side edge; and a first protective layer, wherein at least part of the first protective layer is in direct contact with the first side edge exposed by the through holes.

### CROSS-REFERENCE TO RELATED APPLICATIONS

The present application is a U.S. National Phase Entry of International PCT Application No. PCT/CN2025/072529 having an international filing date of Jan. 15, 2025, which claims priority to Chinese Patent Application No. 202410102841.7, filed to the CNIPA on Jan. 24, 2024 and entitled “Display Module and Preparation Method Therefor, and Display Device”, contents of which should be interpreted as being incorporated into the present application by reference.

### TECHNICAL FIELD

The present disclosure relates to, but is not limited to, the field of display technologies, and particularly to a display module and a preparation method therefor, and a display device.

### BACKGROUND

An organic light emitting diode (OLED) and a quantum dot light emitting diode (QLED) are active light emitting display devices and include advantages of self-illumination, a wide viewing angle, a high contrast ratio, low power consumption, an extremely high reaction speed, lightness and thinness, flexibility, and a low cost, etc. With constant development of display technologies, a flexible display device (Flexible Display) in which an OLED or a QLED is used as a light emitting device and signal control is performed through a thin film transistor (TFT) has become a mainstream product in the field of display at present.

The light-emitting device of an Active Matrix Organic Light Emitting Diode (AMOLED) panel is an organic light-emitting diode, and the AMOLED drives the OLED to emit light by driving a thin film transistor to generate a drive current.

### SUMMARY

The present disclosure provides a display module, including:
a display substrate including a display area and a first bonding area and a second bonding area sequentially disposed on one side of the display area, a bonding pad being disposed on the second bonding area;
an integrated circuit chip bonded to the first bonding area, the integrated circuit chip including a first side edge on a side close to the bonding pad;
a flexible circuit board bonded to the bonding pad of the second bonding area and covering the bonding pad, through holes being formed in the flexible circuit board, and the through holes exposing at least part of the first side edge;
a first protective layer, at least part of the first protective layer being in direct contact with the first side edge exposed by the through holes.

In an exemplary implementation, a through hole of the through holes includes a first sidewall located on a side of the first side edge close to the bonding pad, and the first protective layer is in direct contact with at least part of the first sidewall.

In an exemplary implementation, a vertical distance between the first side edge and an edge of the bonding pad close to the first side edge is greater than or equal to 1.1 mm and less than or equal to 3.1 mm.

In an exemplary implementation, a vertical distance between the first side edge and the first sidewall is greater than or equal to 0.01 mm and less than or equal to 0.7 mm.

In an exemplary implementation, the bottom of the first protective layer is in direct contact with the display substrate.

In an exemplary implementation, the first protective layer includes an epoxy resin adhesive or a photosensitive adhesive.

In an exemplary implementation, the integrated circuit chip further includes edge portions located on other sides of the integrated circuit chip, and the display module further includes a second protective layer that is in direct contact with at least a part of the edge portions of other sides of the integrated circuit chip.

In an exemplary implementation, the edge portions of other sides of the integrated circuit chip include a second side edge, a third side edge, and a fourth side edge. The second side edge is located on a side of the first side edge away from the bonding pad, the third side edge and the fourth side edge are respectively connected to two ends of the first side edge. The second protective layer includes a first sub-protective layer, a second sub-protective layer, and a third sub-protective layer. The first sub-protective layer is in direct contact with at least a part of the second side edge, the second sub-protective layer is in direct contact with at least a part of the third side edge, and the third sub-protective layer is in direct contact with at least a part of the fourth side edge.

In an exemplary implementation, a first end of the first protective layer covers the second sub-protective layer, and a second end of the first protective layer covers the third sub-protective layer.

In an exemplary implementation, the first end of the first sub-protective layer and the second sub-protective layer are stacked on each other, and/or the second end of the first sub-protective layer and the third sub-protective layer are stacked on each other.

In an exemplary implementation, the through holes expose edges on other sides of the integrated circuit chip.

In an exemplary implementation, shapes of the through holes include a rectangular shape. In an exemplary implementation, the display substrate further includes a bending area disposed between the display area and the first bonding area, and the bending area is configured to bend the first bonding area and the second bonding area to a backlight side of the display area.

In an exemplary implementation, a heat dissipation layer and a bending protective layer are also included. The heat dissipation layer is disposed on the backlight side of the display area. The bending protective layer is disposed on a side of the heat dissipation layer away from the display area, and is connected to the second bonding area. A sidewall of a stacked structure that is formed by the second bonding area and the bending protective layer and away from the bending area is substantially flush, a sidewall of the heat dissipation layer away from the bending area is farther away from the bending area compared with the sidewall of the stacked structure. The sidewall of the stacked structure and a surface of the heat dissipation layer form an accommodation space configured to accommodate a battery.

In an exemplary implementation, the third protective layer is further included. The third protective layer is located on a side of the bonding pad away from the integrated circuit chip, a side surface of the third protective layer is in direct contact with the flexible circuit board, and a bottom surface of the third protective layer is in direct contact with the display substrate.

The present disclosure further provides a display device, including the display module described above.

An embodiment of the present disclosure further provides a preparation method for a display module, including:

providing a display substrate on which a bonding pad is disposed; bonding an integrated circuit chip on the display substrate, wherein the integrated circuit chip includes a first side edge on a side close to the bonding pad;

providing a flexible circuit board, which is provided with through holes; bonding the flexible circuit board with the bonding pad of the display substrate, wherein the through holes expose at least part of the first side edge;

coating a first protective layer on the first side edge exposed by the through holes.

In an exemplary implementation, a through hole of the through holes includes a first sidewall on a side close to the bonding pad, and the first protective layer is coated on the first side edge and the first sidewall simultaneously.

In an exemplary implementation, the integrated circuit chip further includes edge portions located on other sides of the integrated circuit chip. Before the flexible circuit board is bonded to the bonding pad of the display substrate, a second protective layer is coated on the edge portions of other sides of the integrated circuit chip.

Other features and advantages of the present application will be set forth in the specification which follows, and in part will become apparent from the specification, or may be learned by practice of the present application. Other advantages of the present application may be achieved and obtained through solutions described in the specification and drawings.

### BRIEF DESCRIPTION OF DRAWINGS

Accompanying drawings are intended to provide an understanding of technical solutions of the present application and constitute a part of the specification, and are used to explain the technical solutions of the present application together with embodiments of the present application, and do not constitute limitations on the technical solutions of the present application.

Accompanying drawings are intended to provide an understanding of technical solutions of the present application and constitute a part of the specification, and are used to explain the technical solutions of the present application together with embodiments of the present application, and do not constitute limitations on the technical solutions of the present application.

FIG. 1 is a schematic diagram of a structure of a display device;

FIG. 2 is a schematic diagram of a structure of a display substrate according to an embodiment of the present application;

FIG. 3 is a schematic diagram of a sectional structure of a display area of a display module;

FIG. 4 is a schematic diagram of a sectional structure of a display module according to an exemplary embodiment of the present disclosure;

FIG. 5 is a schematic diagram of a planar structure of a display substrate and a flexible circuit board of a display module according to an exemplary embodiment of the present disclosure;

FIG. 6 is a schematic diagram of a planar structure of a display substrate and a flexible circuit board of a display module according to an exemplary embodiment of the present disclosure;

FIG. 7a is a schematic diagram of a sectional structure of a display module in a related art;

FIG. 7b is a schematic diagram of a planar structure of a display module in a related art.

### DETAILED DESCRIPTION

To make objectives, technical solutions, and advantages of the present disclosure clearer, the embodiments of the present disclosure will be described in detail below with reference to the accompanying drawings. It is to be noted that implementations may be implemented in multiple different forms. Those of ordinary skills in the art may easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display module and a quantity of sub-pixels in each pixel are not limited to numbers shown in the drawings. The drawings described in the present disclosure are schematic structural diagram only, and one implementation of the present disclosure is not limited to shapes, numerical values, or the like shown in the drawings.

Ordinal numerals “first”, “second”, “third” and the like in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside” and the like for indicating directional or positional relationships are used to illustrate positional relationships between the constituent elements with reference to the accompanying drawings, not to indicate or imply that involved devices or elements are required to include specific orientations or are structured and operated in the specific orientations but only to easily describe the present specification and simplify the description, and thus should not be understood as limitations on the present disclosure. The positional relationships between the constituent elements may be changed as appropriate based on a direction according to which each constituent element is described. Therefore, appropriate replacements based on situations are allowed, which is not limited to the expressions in the specification.

In the specification, unless otherwise explicitly specified and defined, terms “mounting”, “coupling”, and “connection” should be understood in a broad sense. For example, a connection may be a fixed connection, or a detachable connection, or an integral connection; it may be a mechanical connection or an electrical connection; it may be a direct connection, or an indirect connection through a middleware, or an internal communication between two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor includes a channel area between the drain electrode (drain electrode terminal, drain area, or drain) and the source electrode (source electrode terminal, source area, or source), and a current can flow through the drain electrode, the channel area, and the source electrode. It is to be noted that in the specification, the channel area refers to an area through which a current mainly flows.

In the specification, a first pole may be a drain electrode, and a second pole may be a source electrode. Or, the first pole may be a source electrode, and the second pole may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as a “source terminal” and a “drain terminal”, are interchangeable in the specification.

In the specification, an “electrical connection” includes a case that constituent elements are connected together through an element including a certain electrical action. The “element including a certain electrical action” is not particularly limited as long as electrical signals between the connected constituent elements may be sent and received. Examples of the “element including a certain electrical action” not only include an electrode and a wiring, but also include a switching element such as a transistor, a resistor, an inductor, a capacitor, other elements including various functions, etc.

In the specification, “parallel” refers to a state in which an angle formed by two straight lines is above −10° and below 10°, and thus may include a state in which the angle is above- 5°and below 5°. In addition, “perpendicular” refers to a state in which an angle formed by two straight lines is above 80° and below 100°, and thus may include a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulating layer” sometimes.

A triangle, rectangle, trapezoid, pentagon, or hexagon, or the like in the specification is not strictly defined, and it may be an approximate triangle, rectangle, trapezoid, pentagon, or hexagon, or the like. There may be some small deformations caused by tolerance, and there may be a chamfer, an arc edge, deformation, etc.

In the present disclosure, “about” means that a boundary is not defined so strictly and numerical values within process and measurement error ranges are allowed.

FIG. 7a is a schematic diagram of a sectional structure of a display module in a related art; FIG. 7b is a schematic diagram of a planar structure of a display module in a related art. In an exemplary implementation, as shown in FIGS. 7a and 7b, the display module of the related art includes a display substrate 1′ and a flexible circuit board 2′. The flexible circuit board 2′ is bonded to the display substrate 1′. The display substrate 1′ includes a display area 100′ and a bending area 20′, a first bonding area 40′, and a second bonding area 50′ disposed sequentially on a side of the display area 100′. The display area 100′ includes a light emitting side that can display an image and a backlight side 10-2′ that does not display an image. The bending area 20′ is configured to bend the first bonding area 40′ and the second bonding area 50′ to the backlight side 10-2′ of the display area 100′. An Integrated Circuit chip(IC) 3′ is provided on the first bonding area 40′, and a bonding pad 51′ is provided on the second bonding area 50′, and the bonding pad 51′ can be configured to be bonded to the flexible circuit board 2′. A blind groove 7′ is provided in the flexible circuit board 2′, the blind groove 7 ‘does not penetrate the flexible circuit board 2’, and the blind groove 7 ‘is configured to accommodate the integrated circuit chip 3’. The periphery of the integrated circuit chip 3′ is provided with a protective layer 6′.

The preparing process of the display module of the related art may include:
(1) cutting to form the display substrate;
(2) bonding the integrated circuit chip to the first bonding area of the display substrate;
(3) coating the protective layer around the periphery of the integrated circuit chip;
(4) bonding the flexible circuit board to the bonding pad of the display substrate, wherein the flexible circuit board covers the bonding pad of the display substrate and the integrated circuit chip, and the integrated circuit chip is located in the blind groove of the flexible circuit board;
(5) bending the bonding pad of the display substrate to the backlight side of the display area through the bending area.

Through the research of the inventor of the present application, it is found that, in the display module of the related art, the protective layer is firstly coated around the periphery of the integrated circuit chip, and the flexible circuit board is then bonded to the bonding pad of the display substrate. In order to prevent the protective layer from contaminating the bonding pad, it is required to ensure that a certain distance between the integrated circuit chip and the bonding pad is kept, and the distance cannot be reduced, otherwise, the protective layer will contaminate the bonding pad, which results in poor contact after bonding the flexible circuit board, and then leads to abnormal display failure of the display module. The large distance between the integrated circuit chip and the bonding pad squeezes the accommodation space of the battery and reduces the capacity of the battery.

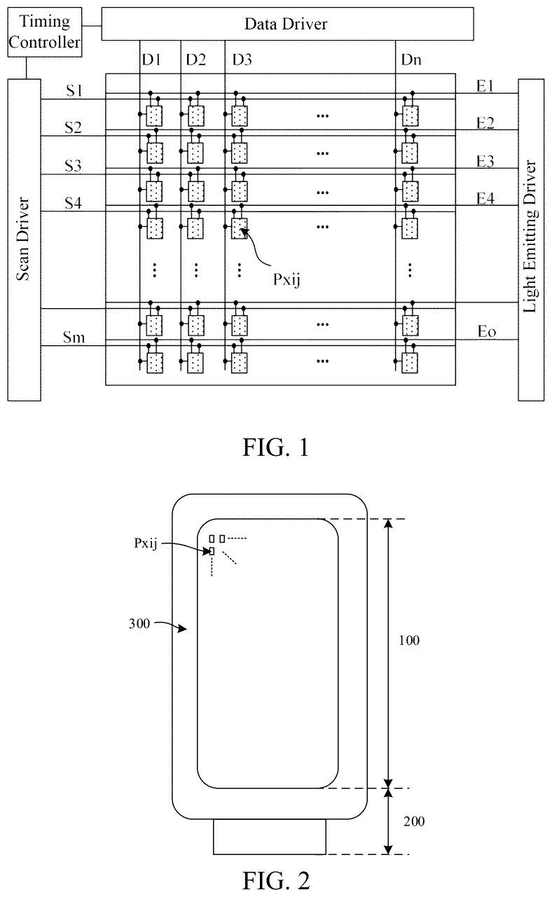

FIG. 1 is a schematic diagram of a structure of a display device. As shown in FIG. 1, the display device may include a timing controller, a data driver, a scan driver, a light emitting driver, and a pixel array. The timing controller is connected with the data driver, the scan driver, and the light emitting driver, respectively. The data driver is respectively connected with a plurality of data signal lines (e.g., D1 to Dn), the scan driver is respectively connected with a plurality of scan signal lines (e.g., S1 to Sm), and the light emitting driver is respectively connected with a plurality of light emitting control lines (e.g., E1 to Eo). Among them, n, m, and o may be natural numbers. The pixel array may include a plurality of sub-pixels Pxij, wherein i and j may be natural numbers. At least one of the sub-pixels Pxij may include a pixel circuit and a light emitting device connected with the pixel circuit. The pixel circuit may be respectively connected with a scan signal line, a light emitting control line, and a data signal line.

In an exemplary implementation, the timing controller may provide the data driver with a grayscale value and a control signal which are suitable for a specification of the data driver, provide the scan driver with a clock signal and a scan start signal and the like which are suitable for a specification of the scan driver, and provide the light emitting driver with a clock signal and an emission stop signal and the like which are suitable for a specification of the light emitting driver. The data driver may generate data voltages to be provided to the data signal lines D1, D2, D3, . . . , and Dn using the grayscale value and the control signal that are received from the timing controller. For example, the data driver may sample the grayscale value by using a clock signal, and apply a data voltage corresponding to the grayscale value to the data signal lines D1 to Dn by taking a pixel column as a unit. The scan driver may generate a scan signals to be provided to the scan signal lines S1, S2, S3, . . . , and Sm by receiving the clock signal and the scan start signal from the timing controller. For example, the scan driver may sequentially provide a scan signal including an on-level pulse to the scan signal lines S1 to Sm. For example, the scan driver may be constructed in a form of a shift register, and may generate a scan signal in a manner of sequentially transmitting a scan start signal provided in a form of an on-level pulse to a next-stage circuit under control of a clock signal. The light emitting driver may receive a clock signal, an emission stop signal, etc., from the timing controller to generate a light emitting control signal to be provided to the light emitting control lines E1, E2, E3, . . . , and Eo. For example, the light emitting driver may sequentially provide an emission signal including an off-level pulse to the light emitting control lines E1 to Eo. For example, the light emitting driver may be constructed in a form of a shift register and generate a light emitting control signal in a manner of sequentially transmitting an emission stop signal provided in a form of an off-level pulse to a next-stage circuit under control of a clock signal.

FIG. 2 is a schematic diagram of a structure of a display substrate panel according to an embodiment of the present application. In an exemplary implementation, as shown in FIG. 2, the display substrate may include a display area 100, a bonding area 200 located on a side of the display area 100, and a bezel area 300 located at other sides of the display area 100.

In some examples, the display module may be a flexible substrate. Accordingly, the display module may be deformable, for example, may be crimped, bent, folded, or curled.

In an exemplary implementation, the bonding area 200 may include a lead line area, a bending area, a drive chip area, and a bonding pin area that are disposed sequentially along a direction away from the display area 100. The lead area is connected to the display area 100 and at least includes lead-out lines. A plurality of lead-out lines are configured to be connected with the data signal lines of the display area 100 in a fan-out trace manner. The bending area is connected to the lead line area and may include a composite insulating layer provided with a groove, and is configured to enable the drive chip area and the bonding pin area to be bent to a back of the display area 100. The drive chip area may be provided with an Integrated Circuit (IC) that may be configured to connect with a plurality of lead-out lines. The bonding pin area may include a bonding pad that may be configured to bond and connect with an external Flexible Printed Circuit (FPC).

In some examples, the display area 100 may be a planar area including a plurality of sub-pixels Pxij that form a pixel array, the plurality of sub-pixels Pxij may be configured to display a dynamic picture or a static image, and the display area 100 may be referred to as an Active area (AA).

In an exemplary implementation, the display area 100 of the display module may include a plurality of pixel units arranged in a matrix. For example, at least one pixel unit may include a first sub-pixel emitting first-color light, a second sub-pixel emitting second-color light, and a third sub-pixel and a fourth sub-pixel emitting third-color light.

In an exemplary implementation, the first sub-pixel may be a red sub-pixel (R) emitting red light, the second sub-pixel may be a blue sub-pixel (B) emitting blue light, and the third sub-pixel and the fourth sub-pixel may be green sub-pixels (G) emitting green light. In some examples, a shape of a light emitting device of a sub-pixel may be a rectangle, a diamond, a pentagon, or a hexagon. Light emitting devices of four sub-pixels may be arranged in a diamond-shaped manner to form an RGBG pixel arrangement. In another exemplary implementation, the light emitting devices of four sub-pixels may be arranged side by side horizontally, side by side vertically, or in a manner of a square, etc., which is not limited here in the present disclosure. In some other exemplary embodiments, the pixel unit may include three sub-pixels, the light emitting device of the three sub-pixels may be arranged side by side horizontally, side by side vertically, or in a manner like a Chinese character “u” or the like, which is not limited in the present disclosure.

In an exemplary implementation, the sub-pixel Pxij may include a pixel circuit and a light emitting device. The pixel circuit is electrically connected to a scan signal line, a data signal line, and a light emitting control line, respectively. The pixel circuit may be configured to receive a data voltage transmitted by the data signal line under the control of the scan signal line and the light emitting control line, and output a corresponding current to the light emitting device. The light emitting device in each sub-pixel is connected with a pixel circuit of the sub-pixel where the light emitting device is located, and the light emitting device is configured to emit light with corresponding brightness in response to a current output by the pixel circuit of the sub-pixel where the light emitting device is located.

In an exemplary implementation, the light emitting device may include one of an organic light emitting diode (OLED), a micro light emitting diode (LED), a quantum dot light emitting diode (QLED). The sub-pixel may emit light, such as red light, green light, blue light or white light, by the light emitting device.

In an exemplary implementation, the display module includes a display area 100 including a rectangular shape. In some embodiments, the display area 100 may also include a circular shape, an elliptical shape, or a polygonal shape such as a triangle and a pentagon.

In an exemplary implementation, the display module may be a tablet display module. In some embodiments, the display module may be other types of display modules as well. For example, a flexible display module, a foldable display module, a rollable display module, and the like.

The light-emitting device in the display module in accordance with this embodiment being an organic light-emitting diode (OLED) will be described as an example hereinafter, but the display module in accordance with this embodiment is not limited thereto. In another embodiment, the light-emitting device in the display module may be a micro light-emitting diode (LED) or a quantum dot light-emitting diode (QLED) or the like. For example, a light emitting layer of the light emitting device in the display module may include an organic material, an inorganic material, quantum dots, an organic material and quantum dots, an inorganic material and quantum dots, or an organic material, an inorganic material and quantum dots.

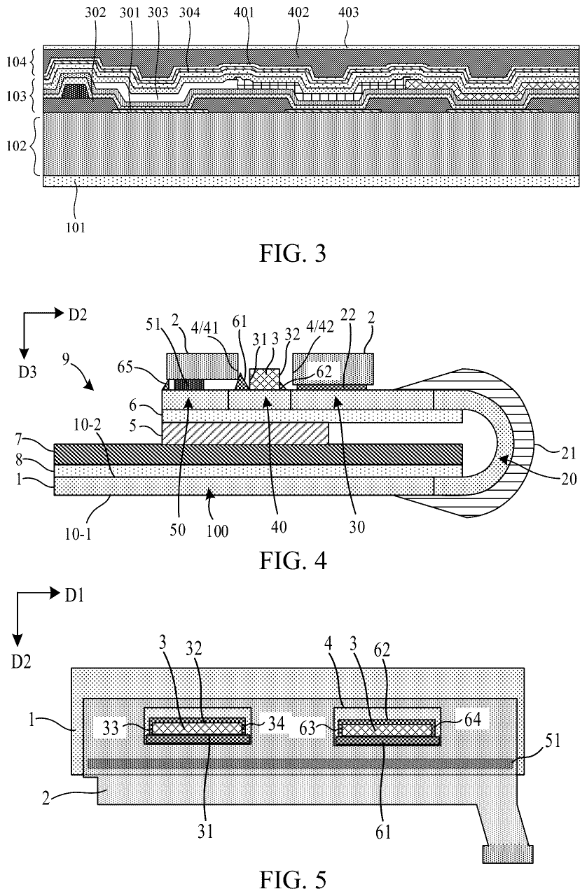

FIG. 3 is a schematic diagram of a sectional structure of a display area of a display module. FIG. 3 illustrates structures of three sub-pixels in the display area 100. As shown in FIG. 3, in a direction perpendicular to the display module, the display module may include a base substrate 101, and a drive circuit layer 102, a light emitting structure layer 103 and an encapsulation structure layer 104 which are sequentially arranged on the base substrate 101. In some possible implementations, the display module may include other film layers, such as a touch structure layer, which is not limited here in the present disclosure.

In an exemplary implementation, the base substrate 101 may be a flexible base substrate, or may be a rigid base substrate. The drive circuit layer 102 of each sub-pixel may include a pixel circuit composed of multiple transistors and capacitors. The light emitting structure layer 103 of each sub-pixel may at least include an anode 301, a pixel definition layer 302, an organic emitting layer 303 and a cathode 304. The anode 301 is connected to the pixel circuit, the organic emitting layer 303 is connected with the anode 301, the cathode 304 is connected to the organic emitting layer 303, and the organic emitting layer 303 emits light of a corresponding color under driving of the anode 301 and the cathode 304. The encapsulation structure layer 104 may include a first encapsulation layer 401, a second encapsulation layer 402, and a third encapsulation layer 403 which are stacked, wherein the first encapsulation layer 401 and the third encapsulation layer 403 may be made of an inorganic material, the second encapsulation layer 402 may be made of an organic material, and the second encapsulation layer 402 is disposed between the first encapsulation layer 401 and the third encapsulation layer 403 to form a laminated structure of an inorganic material/an organic material/an inorganic material, which may ensure that external water vapor cannot enter the light emitting structure layer 103.

In an exemplary implementation, the organic light emitting layer 303 may include an emitting layer (EML), and any one or more of following layers: a hole injection layer (HIL), a hole transport layer (HTL), an electron block layer (EBL), a hole block layer (HBL), an electron transport layer (ETL), and an electron injection layer (EIL). In some examples, one or more layers of hole injection layers, hole transport layers, electron block layers, hole block layers, electron transport layers, and electron injection layers of all sub-pixels may be a common layer with various layer being connected together. Emitting layers of adjacent sub-pixels may be overlapped slightly, or may be mutually isolated.

The present application further provides a display module, including:
a display substrate provided with a bonding pad;
an integrated circuit chip disposed on the display substrate, the integrated circuit chip including a first side edge on a side close to the bonding pad;
a flexible circuit board bonded to the bonding pad of the display substrate and covering the bonding pad, through holes being formed in the flexible circuit board, and the through holes exposing at least part of the first side edge;
a first protective layer, at least part of the first protective layer being in direct contact with the first side edge exposed by the through holes.

The display module in the present disclosure is illustrated with examples below through some exemplary embodiments.

FIG. 4 is a schematic diagram of a sectional structure of a display module according to an exemplary embodiment of the present disclosure. In an exemplary implementation, as shown in FIG. 4, the display module of the exemplary embodiment of the present disclosure includes a display substrate 1, a flexible circuit board 2, and an Integrated Circuit chip 3 (IC). The flexible circuit board 2 and the integrated circuit chip 3 are both bonded to the display substrate 1.

In an exemplary implementation, the display substrate 1 includes a display area 100, and a bending area 20, a lead line area 30, a first bonding area 40, and a second bonding area 50 disposed sequentially on a side of the display area 100. The display area 100 is configured to display an image, and the display area 100 includes a light emitting side 10-1 and a backlight side 10-2. The light emitting side 10-1 and the backlight side 10-2 are located on the opposite sides of the display area 100 in a thickness direction. The light emitting side 10-1 can display an image and the backlight side 10-2 does not display an image. The bending area 20 is configured to bend the lead line area 30, the first bonding area 40, and the second bonding area 50 to the backlight side 10-2 of the display area 100. The bending area 20 includes a C-shape in a cross section perpendicular to the direction of the display substrate 1, a first end of the bending area 20 is connected to the display area 100, and a second end of the bending area 20 is bent to the backlight side 10-2 of the display area 100 and is connected to the lead line area 30. The lead line area 30, the first bonding area 40, and the second bonding area 50 are located on the backlight side 10-2 of the display area 100. The lead line area 30, the first bonding area 40, and the second bonding area 50 are substantially parallel to the display area 100. A first end of the lead line area 30 is connected to the second end of the bending area 20, a second end of the lead line area 30 extends in a opposite direction of the second direction D2, and is connected to the first bonding area 40. The lead line area 30 includes a plurality of lead-out lines configured to be connected with a plurality of data signal lines of the display area 100. A first end of the first bonding area 40 is connected to the second end of the lead line area 30, and a second end of the first bonding area 40 extends in the opposite direction of the second direction D2, and is connected to the second bonding area 50. The first bonding area 40 may be configured to be connected with an Integrated Circuit chip 3 (IC) disposed on a side of the first bonding area 40 away from the display area 100, and the integrated circuit chip 3 may be configured to be connected to a plurality of lead-out lines of the lead line area 30. A first end of the second bonding area 50 is connected to the second end of the first bonding area 40, a second end of the second bonding area 50 extends in the opposite direction of the second direction D2. A side of the second bonding area 50 away from the display area 100 is provided with a bonding pad 51, and the bonding pad 51 may be configured to be connected to the flexible circuit board 2.

In an exemplary implementation, at least a part of the flexible circuit board 2 is disposed on a side of the lead line area 30, the first bonding area 40, and the second bonding area 50 away from the display area 100, and at least a part of the flexible circuit board 2 covers the side of the lead line area 30, the first bonding area 40, and the second bonding area 50 away from the display area 100. The flexible circuit board 2 is configured to be bonded to the bonding pad 51 of the second bonding area 50 and cover the bonding pad 51.

In an exemplary implementation, the flexible circuit board 2 is provided with through holes 4, and the through holes 4 penetrate the flexible circuit board 2 along a thickness direction of the flexible circuit board 2. The through holes 4 expose at least a part of the integrated circuit chip 3. For example, the through holes 4 expose the entire integrated circuit chip 3.

In an exemplary implementation, the integrated circuit chip 3 is located on a side of the bonding pad 51 in a direction parallel to of the display module. The integrated circuit chip 3 includes a first side edge 31 on a side close to the bonding pad 51 and an edge portion located on other sides of the integrated circuit chip 3. The display module of the embodiment of the present disclosure further includes a first protective layer 61 and a second protective layer. At least part of the first protective layer 61 is in direct contact with the first side edge 31 of the integrated circuit chip 3 exposed by the through hole 4, the first protective layer 61 is configured to seal the first side edge 31 of the integrated circuit chip 3, the second protective layer is in direct contact with at least part of the edge portion of other sides of the integrated circuit chip 3, and the second protective layer is configured to seal the edge portions of other sides of the integrated circuit chip 3.

In an exemplary implementation, both the first protective layer 61 and the second protective layer may include an epoxy resin adhesive or a photosensitive adhesive.

In an exemplary implementation, the flexible circuit board 2 separates the first protective layer 61 from the bonding pad 51, and the first protective layer 61 is not in contact with the bonding pad 51, so as to prevent the first protective layer 61 from affecting the conductivity of the bonding pad 51.

In the display module of the embodiment of the present disclosure, the first side edge 31 of the integrated circuit chip 3 is sealed through the first protective layer 61, so as to prevent water and oxygen from entering the integrated circuit chip 3.

In the display module of the embodiment of the present disclosure, the first protective layer 61 is separated from the bonding pad 51 by the flexible circuit board 2, so as to prevent the first protective layer 61 from contaminating the bonding pad 51.

In an exemplary implementation, the integrated circuit chip 3 includes a first side edge 31 on a side close to the bonding pad 51 and a second side edge 32 on a side away from the bonding pad 51. The through hole 4 includes a first sidewall 41 on a side close to the bonding pad 51 and a second sidewall 42 on a side away from the bonding pad 51. The first sidewall 41 is disposed on a side of the first side edge 31 close to the bonding pad 51, the second sidewall 41 is disposed on a side of the first side edge 31 away from the bonding pad 51, and the through hole 4 exposes the first side edge 31 of the integrated circuit chip 3. For example, the first sidewall 41 is disposed on a side of the first side edge 31 close to the bonding pad 51, the second sidewall 41 is disposed on a side of the second side edge 32 away from the bonding pad 51, and the through hole 4 exposes the first side edge 31, the second side edge 32, and an area between the first side edge 31 and the second side edge 32 of the integrated circuit chip 3.

In an exemplary implementation, the first protective layer 61 is in direct contact with at least part of the first sidewall 41, and the first protective layer 61 is configured to seal the first sidewall 41 of the through hole 4.

In the display module of the embodiment of the present disclosure, the first side edge 31 of the integrated circuit chip 3 and the first sidewall 41 of the through hole 4 can be simultaneously sealed through the first protective layer 61, so as to prevent water and oxygen from entering the integrated circuit chip 3 and the bonding pad covered by the flexible circuit board 2, thereby simplifying the process.

In an exemplary implementation, the bottom of the first protective layer 61 is in direct contact with a surface of the first bonding area 40 away from the display area 100.

In an exemplary implementation, the second protective layer includes a first sub-protective layer 62. At least part of the first sub-protective layer 62 is in direct contact with the second side edge 32 of the integrated circuit chip 3, the bottom of the first sub-protective layer 62 is in direct contact with the surface of the first bonding area 40 away from the display area 100, and the first sub-protective layer 62 is configured to seal the second side edge 32 of the integrated circuit chip 3.

In the display module of the embodiment of the present disclosure, the second side edge 32 of the integrated circuit chip 3 is sealed through the first sub-protective layer 62, so as to prevent water and oxygen from entering the integrated circuit chip 3.

In an exemplary implementation, the display module of the embodiment of the present disclosure further includes a third protective layer 65 located on a side of the bonding pad 51 away from the integrated circuit chip 3. A side surface of the third protective layer 65 is in direct contact with the flexible circuit board 2, a bottom surface of the third protective layer 65 is in direct contact with a surface of the second bonding area 50 away from the display area 100, and the third protective layer 65 is configured to seal the flexible circuit board 2.

In an exemplary implementation, the third protective layer 65 is not in contact with the bonding pad 51, and the third protective layer 65 is prevented from affecting the conductivity of the bonding pad 51.

In an exemplary implementation, the third protective layer 65 includes an epoxy resin adhesive or a photosensitive adhesive.

In an exemplary implementation, the display module of the embodiment of the present disclosure further includes an adhesive layer 22 disposed between the flexible circuit board 2 and the lead line area 30. An upper surface of the adhesive layer 22 is in direct contact with a surface of the flexible circuit board 2 close to the lead line area 30, a lower surface of the adhesive layer 22 is in direct contact with a surface of the lead line area 30 away from the display area 100, and the adhesive layer 22 is configured to connect the flexible circuit board 2 and the display substrate 1 together.

In an exemplary implementation, the display module of the embodiment of the present disclosure further includes a first back film 8 disposed on the backlight side 10-2 of the display area 100 of the display substrate 1, and the first back film 8 is in direct contact with the backlight side 10-2 of the display area 100.

In an exemplary implementation, the display module of the embodiment of the present disclosure further includes a heat dissipation layer 7, the heat dissipation layer 7 is disposed on a side of the first back film 8 away from the display area 100, and the heat dissipation layer 7 is in direct contact with the first back film 8. The heat dissipation layer 7 may include a carbon plate.

In an exemplary implementation, the display module of the embodiment of the present disclosure further includes a bending protective layer 5, the bending protective layer 5 is disposed on a side of the heat dissipation layer 7 away from the display area 100, a surface on a side of the bending protective layer 5 is in direct contact with the heat dissipation layer 7, and a surface on the other side of the bending protective layer 5 is connected to the first bonding area 40 and the second bonding area 50 through a second back film 6.

In an exemplary implementation, the display module of the embodiment of the present disclosure further includes a second back film 6 disposed on a side of the bending protective layer 5 away from the display area 100, a lower surface of the second back film 6 is in direct contact with the bending protective layer 5, and an upper surface of the second back film 6 is in direct contact with a surface of a flat plate portion of the display substrate 1 close to the display area 100.

In an exemplary implementation, a sidewall of a stacked structure formed by the second bonding area 50, the second back film 6, and the bending protective layer 5 away from the bending area 20 is substantially flush, the sidewall of the stacked structure away from the bending area 20 extends along a direction perpendicular to the display area 100, and a sidewall of the heat dissipation layer 7 away from the bending area 20 is farther away from the bending area 20 compared with the sidewall of the stacked structure away from the bending area 20. The sidewall of the stacked structure away from the bending area 20 and a surface of the heat dissipation layer 7 form an accommodation space 9, which may be configured to accommodate a battery.

The above structure of the display module of the embodiment of the present disclosure can reduce a distance between the integrated circuit chip 3 and the bonding pad 51, that is, a distance between the integrated circuit chip 3 and the bonding pad 51 in the second direction D2, thereby increasing a length of the accommodation space 9 in the second direction D2. For example, the distance between the integrated circuit chip 3 and the bonding pad 51 can be reduced by 2 mm, and the length of the accommodation space 9 in the second direction D2 is increased by 2 mm, thereby increasing the capacity of the battery.

In an exemplary implementation, the display module of the embodiment of the present disclosure further includes a protective film 21, and at least a part of the protective film 21 covers an outer surface of the bending area 20.

FIG. 5 is a schematic diagram of a planar structure of a display substrate and a flexible circuit board of a display module according to an exemplary embodiment of the present disclosure. In an exemplary implementation, as shown in FIG. 5, the flexible circuit board 2 covers at least a part of the display substrate 1, the flexible circuit board 2 is bonded to the bonding pad 51 of the display substrate 1, and covers the bonding pad 51 of the display substrate 1. The through holes 4 of the flexible circuit board 2 are located on a side of the bonding pad 51 of the display substrate 1 in the opposite direction of the second direction D2, the shape of the through holes 4 of the flexible circuit board 2 include a rectangle, and the through holes 4 expose all of the integrated circuit chip 3.

In an exemplary implementation, the integrated circuit chip 3 of the display substrate 1 is located on a side of the bonding pad 51 of the display substrate 1 in the opposite direction of the second direction D2, and the integrated circuit chip 3 is located in the through hole holes 4, and is exposed by the through holes 4. The shape of the integrated circuit chip 3 includes a rectangular shape, the integrated circuit chip 3 includes a first side edge 31, a second side edge 32, a third side edge 33, and a fourth side edge 34. The first side edge 31 and the second side edge 32 are long side edges and are located on opposite sides of the integrated circuit chip 3 in the second direction D2, the first side edge 31 is located on a side close to the bonding pad 51, and the second side edge 32 is located on a side of the first side edge 31 away from the bonding pad 51. The third side edge 33 and the fourth side edge 34 are short side edges and are located on opposite sides of the integrated circuit chip 3 in the first direction D1, and the third side edge 33 and the fourth side edge 34 are respectively connected to two ends of the first side edge 31. The second side edge 32, the third side edge 33, and the fourth side edge 34 are the side portion of other sides of the integrated circuit chip 3. The first direction D1 and the second direction D2 intersect with each other, by way of example, the first direction D1 and the second direction D2 are perpendicular to each other.

In an exemplary implementation, the through hole 4 exposes the first side edge 31, the second side edge 32, the third side edge 33, and the fourth side edge 34 of the integrated circuit chip 3.

In an exemplary implementation, the first protective layer 61 is located on a side of the bonding pad 51 of the display substrate 1 in the opposite direction of the second direction D2, and the first protective layer 61 extends along an outline of the first side edge. The shape of the first protective layer 61 includes a strip shape extending along the first direction D1, and at least part of the first protective layer 61 is in direct contact with the first side edge 31 of the integrated circuit chip 3 exposed by the through hole 4.

In an exemplary implementation, the first protective layer 61 is not in contact with the bonding pad 51, and the first protective layer 61 is separated from the bonding pad 51 by the flexible circuit board 2 to prevent the first protective layer 61 from affecting the conductivity of the bonding pad 51.

In an exemplary implementation, the first protective layer 61 is in direct contact with at least part of the first sidewall 41, and, for example, the first protective layer 61 covers all of the first sidewall 41.

In an exemplary implementation, the display module of the embodiment of the present disclosure further includes a second protective layer, the second protective layer is in direct contact with the edge portion of other sides of the integrated circuit chip 3, and the second protective layer is configured to seal the edge portion of other sides of the integrated circuit chip 3.

In an exemplary implementation, the second protective layer includes a first sub-protective layer 62 located on a side of the first protective layer 61 away from the bonding pad 51. The shape of the first sub-protective layer 62 includes a strip shape extending along the first direction D1, and the first sub-protective layer 62 is in direct contact with at least a part of the second side edge 32 of the integrated circuit chip 3.

In an exemplary implementation, the second protective layer further includes a second sub-protective layer 63. The shape of the second sub-protective layer 63 includes a strip shape extending along the second direction D2, and the second sub-protective layer 63 is in direct contact with at least a part of the third side edge 33 of the integrated circuit chip 3.

In an exemplary implementation, the second protective layer further includes a third sub-protective layer 64. The shape of the third sub-protective layer 64 includes a strip shape extending along the second direction D2, and the third sub-protective layer 64 is in direct contact with at least part of the fourth side edge 34 of the integrated circuit chip 3.

In an exemplary implementation, the first protective layer 61 includes a first end and a second end located at opposite ends of the first protective layer 61 in the first direction D1. The first end of the first protective layer 61 covers a first end of the second sub-protective layer 63, and the second end of the first protective layer 61 covers a first end of the third sub-protective layer 64.

In the display module of the embodiment of the present disclosure, the second sub-protective layer 63 is covered through the first end of the first protective layer 61, thereby ensuring the sealing of the bonding pad 51.

In the display module of the embodiment of the present disclosure, the third sub-protective layer 64 is covered through the second end of the first protective layer 61, thereby ensuring the sealing of the bonding pad 51.

In an exemplary implementation, the first sub-protective layer 62 includes a first end and a second end located at opposite ends of the first sub-protective layer 62 in the first direction D1. The first end of the first sub-protective layer 62 and a second end of the second sub-protective layer 63 are stacked on each other, for example, the first end of the first sub-protective layer 62 covers the second end of the second sub-protective layer 63, or the second end of the second sub-protective layer 63 covers the first end of the first sub-protective layer 62. The second end of the first sub-protective layer 62 and a second end of the third sub-protective layer 64 are stacked on each other, for example, the second end of the first sub-protective layer 62 covers the second end of the third sub-protective layer 64, or the second end of the third sub-protective layer 64 covers the second end of the first sub-protective layer 62.

In the display module of the embodiment of the present disclosure, the first sub-protective layer 62 and the second sub-protective layer 63 are stacked on each other, thereby ensuring the sealing of the bonding pad 51.

In the display module of the embodiment of the present disclosure, the first sub-protective layer 62 and the third sub-protective layer 64 are stacked on each other, thereby ensuring the sealing of the bonding pad 51.

Exemplary description is made below through a preparation process of a display module. In an exemplary implementation, the preparation process of the display module of the exemplary embodiment of the present disclosure may include:
(1) cutting and forming a display substrate 1 including a display area 100 and a bending area 20, a first bonding area 40, and a second bonding area 50 disposed sequentially on a side of the display area 100, a bonding pad 51 being disposed on the second bonding area;
(2) forming a protective film 21 on the bending area 20 of the display substrate 1;
(3) bonding the integrated circuit chip 3 to the first bonding area of the display substrate 1, the integrated circuit chip 3 being adjacent to the bonding pad 51, the integrated circuit chip 3 including a first side edge 31 on a side close to the bonding pad 51, and a second side edge 32, a third side edge 33, and a fourth side edge 34 located on other sides of the integrated circuit chip 3;
(4) coating a first sub-protective layer 62 on the second side edge 32, a second sub-protective layer 63 on the third side edge 33, and a third sub-protective layer 64 on the fourth side edge 34;
(5) bonding the flexible circuit board 2 to the bonding pad 51 of the display substrate 1, and the flexible circuit board 2 covering the bonding pad 51 of the display substrate 1, and the through hole 4 of the flexible circuit board 2 exposes at least the first side edge 31 of the integrated circuit chip 3;
(6) coating a first protective layer 61 on the first side edge 31 and the first sidewall 41 of the through hole 4 so that the first protective layer 61 simultaneously seals the first side edge 31 and the first sidewall 41;
(7) forming a heat dissipation layer 7 on the backlight side of the display area 100 of the display substrate 1;
(8) bending the bonding pad 51 of the display substrate 1 to the backlight side of the display area 100 through the bending area 20, and the bonding pad 51 being connected to the backlight side of the display area 100 through the bending protective layer 5 and the heat dissipation layer 7.

In the display module of the embodiment of the present disclosure, after the flexible circuit board 2 is bonded to the bonding pad 51 of the display substrate 1, the first side edge 31 of the integrated circuit chip 3 close to the bonding pad 51 is exposed through the through hole 4, and then the first side edge 31 is sealed by coating the first protective layer 61, and the bonding pad 51 is covered by the flexible circuit board 2 during the coating of the first protective layer 61, thereby avoiding direct contact between the first protective layer 61 and the bonding pad 51.

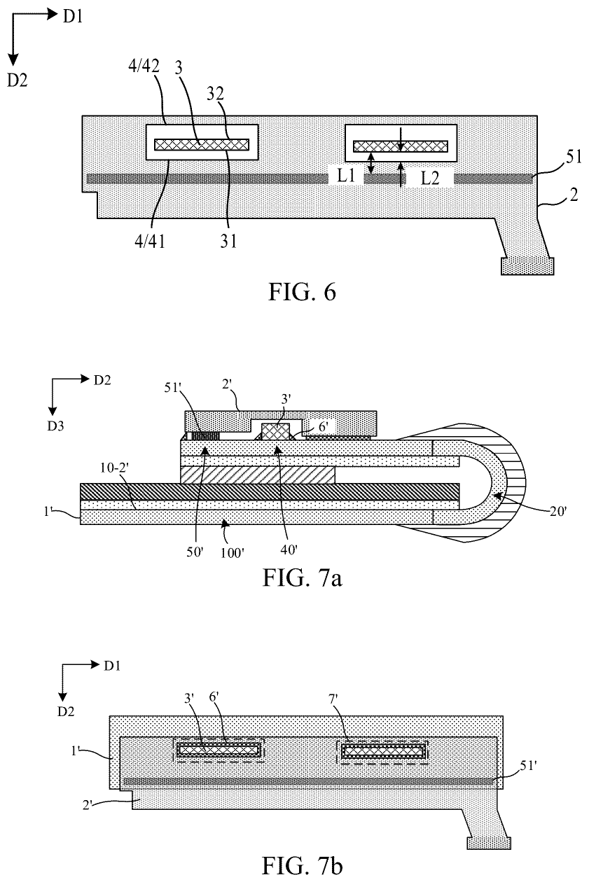

FIG. 6 is a schematic diagram of a planar structure of a display substrate and a flexible circuit board of a display module according to an exemplary embodiment of the present disclosure. In an exemplary implementation, as shown in FIG. 6, the through hole 4 includes a first sidewall 41 and a second sidewall 42 disposed opposite to each other in the second direction D2. The first sidewall 41 extends along the first direction D1, and the first sidewall 41 is located on a side of the first side edge 31 of the integrated circuit chip 3 close to the bonding pad 51. The second sidewall 42 extends along the first direction D1, and the second sidewall 42 is located on a side of the second side edge 32 of the integrated circuit chip 3 away from the bonding pad 51.

In an exemplary implementation, a vertical distance between the first side edge 31 and an edge of the bonding pad 51 close to the first side edge 31 is L1, and L1 is greater than or equal to 1.1 mm and less than or equal to 3.1 mm. For example, L1 is greater than or equal to 1.5 mm and less than or equal to 2 mm.

In an exemplary implementation, a vertical distance between the first side edge 31 and the first sidewall 41 of the through hole 4 is L 2, and L2 is greater than or equal to 0.01 mm and less than or equal to 0.7 mm. For example, L 2 is greater than or equal to 0.1 mm and less than or equal to 0.5 mm.

In the display module of the embodiment of the present disclosure, the vertical distance L2 between the first side edge 31 and the first sidewall 41 of the through hole 4 is greater than or equal to 0.01 mm and less than or equal to 0.7 mm, so that it is ensured that the first protective layer 61 can simultaneously be in contact with the first side edge 31 and the first sidewall 41, and seal the first side edge 31 and the first sidewall 41, thereby simplifying the process.

A display device which includes the aforementioned display module is also provided in the present disclosure. The display device may be any product or component including a display function, such as a mobile phone, a tablet computer, a television, a display, a laptop computer, a digital photo frame, and a navigator, which is not limited in the embodiments of the present disclosure.

The present disclosure further provides a preparation method for a display module, including:
providing a display substrate including a display area and a first bonding area and a second bonding area sequentially disposed on one side of the display area, a bonding pad being disposed on the second bonding area;
bonding an integrated circuit chip on the first bonding area, the integrated circuit chip including a first side edge on a side close to the bonding pad;
providing a flexible circuit board, which is provided with through holes;
bonding the flexible circuit board to the bonding pad of the second bonding area, the through holes exposing at least part of the first side edge;
coating a first protective layer on the first side edge exposed by the through holes.

In an exemplary embodiment, the through hole includes a first sidewall on a side close to the bonding pad, and the first protective layer is coated on the first side edge and the first sidewall simultaneously.

In an exemplary implementation, the integrated circuit chip further includes an edge portion located on sides of the integrated circuit chip. A second protective layer is coated on the edge portion of other sides of the integrated circuit chip before the flexible circuit board is bonded to the bonding pad of the display substrate. After the flexible circuit board is bonded to the bonding pad of the display substrate, a first protective layer is coated on the first side edge exposed by the through hole.

In the display module of the embodiment of the present disclosure, after the flexible circuit board is bonded to the bonding pad of the display substrate, the first protective layer is coated, so that the flexible circuit board covers the bonding pad, and the first protective layer is prevented from contaminating the bonding pad, thereby reducing the distance between the bonding pad and the integrated circuit chip, and increasing the accommodation space for accommodating the battery.

A plurality of embodiments is described in the present application. However, the description is exemplary and unrestrictive. Moreover, it is apparent to those of ordinary skills in the art that there may be more embodiments and implementation solutions within the scope of the embodiments described in the present application. Although many possible combinations of features are shown in the accompanying drawings and discussed in specific implementations, many other combinations of the disclosed features are also possible. Unless expressly limited, any feature or element of any embodiment may be used in combination with, or may replace, any other feature or element in any other embodiment.

The present application includes and conceives combinations of features and elements well known to those of ordinary skills in the art. The embodiments, features and elements that have been disclosed in the present application may be combined with any conventional features or elements to form unique inventive solutions defined by the claims. Any feature or element of any embodiment may also be combined with a feature or an element from another inventive solution to form another unique inventive solution defined by the claims. Therefore, it should be understood that any feature shown and/or discussed in the present application may be implemented independently or in any appropriate combination. Therefore, the embodiments are not to be limited except the limitations by the appended claims and equivalents thereof. Furthermore, various modifications and variations may be made within the protection scope of the appended claims.

Moreover, when describing embodiments including representativity, the specification may have presented a method and/or a process as a particular sequence of acts. However, to an extent that the method or the process does not depend on the specific sequence of the acts described herein, the method or the process should not be limited to the acts with the specific sequence. Those of ordinary skills in the art will understand that other sequences of acts may also be possible. Therefore, the specific sequence of the acts illustrated in the specification should not be interpreted as a limitation on claims. Moreover, the execution of the acts in the claims for the method and/or the process should not be limited to the written sequence, and it can be easily understood by those skilled in the art that these sequences may be changed and still fall within the spirit and scope of the embodiments of the present application.

1. A display module, comprising:
a display substrate comprising a display area and a first bonding area and a second bonding area sequentially disposed on one side of the display area, wherein a bonding pad is disposed on the second bonding area;
an integrated circuit chip bonded to the first bonding area, wherein the integrated circuit chip comprises a first side edge on a side close to the bonding pad;
a flexible circuit board bonded to the bonding pad of the second bonding area and covering the bonding pad, wherein through holes are formed in the flexible circuit board, and the through holes expose at least part of the first side edge; and
a first protective layer, wherein at least part of the first protective layer is in direct contact with the first side edge exposed by the through holes.

2. The display module according to claim 1, wherein a through hole of the through holes comprises a first sidewall located on a side of the first side edge close to the bonding pad, and the first protective layer is in direct contact with at least part of the first sidewall.

3. The display module according to claim 1, wherein a vertical distance between the first side edge and an edge of the bonding pad close to the first side edge is greater than or equal to 1.1 mm and less than or equal to 3.1 mm.

4. The display module according to claim 2, wherein a vertical distance between the first side edge and the first sidewall is greater than or equal to 0.01 mm and less than or equal to 0.7 mm.

5. The display module according to claim 1, wherein the bottom of the first protective layer is in direct contact with the display substrate.

6. The display module according to claim 1, wherein the first protective layer comprises an epoxy resin adhesive or a photosensitive adhesive.

7. The display module according to claim 1, wherein the integrated circuit chip further comprises edge portions located on other sides of the integrated circuit chip, and the display module further comprises a second protective layer that is in direct contact with at least a part of the edge portions of other sides of the integrated circuit chip

8. The display module according to claim 7, wherein
the edge portions of other sides of the integrated circuit chip comprise a second side edge, a third side edge, and a fourth side edge;
the second side edge is located on a side of the first side edge away from the bonding pad, the third side edge and the fourth side edge are respectively connected to two ends of the first side edge;
the second protective layer comprises a first sub-protective layer, a second sub-protective layer, and a third sub-protective layer;
the first sub-protective layer is in direct contact with at least a part of the second side edge, the second sub-protective layer is in direct contact with at least a part of the third side edge, and the third sub-protective layer is in direct contact with at least a part of the fourth side edge.

9. The display module according to claim 8, wherein a first end of the first protective layer covers the second sub-protective layer, and a second end of the first protective layer covers the third sub-protective layer.

10. The display module according to claim 8, wherein a first end of the first sub-protective layer and the second sub-protective layer are stacked on each other, and/or a second end of the first sub-protective layer and the third sub-protective layer are stacked on each other.

11. The display module according to claim 7, wherein the through holes expose the edge portions of other sides of the integrated circuit chip.

12. The display module according to claim 1, wherein shapes of the through holes comprise a rectangular shape.

13. The display module according to claim 1, wherein the display substrate further comprises a bending area disposed between the display area and the first bonding area, and the bending area is configured to bend the first bonding area and the second bonding area to a backlight side of the display area.

14. The display module according to claim 13, further comprising a heat dissipation layer and a bending protective layer; wherein
the heat dissipation layer is disposed on the backlight side of the display area,
the bending protective layer is disposed on a side of the heat dissipation layer away from the display area, and is connected to the second bonding area,
a sidewall of a stacked structure that is formed by the second bonding area and the bending protective layer and away from the bending area is substantially flush,
a sidewall of the heat dissipation layer away from the bending area is farther away from the bending area compared with the sidewall of the stacked structure, and
the sidewall of the stacked structure and a surface of the heat dissipation layer form an accommodation space configured to accommodate a battery.

15. The display module according to claim 1, further comprising a third protective layer; wherein the third protective layer is located on a side of the bonding pad away from the integrated circuit chip, a side surface of the third protective layer is in direct contact with the flexible circuit board, and a bottom surface of the third protective layer is in direct contact with the display substrate.

16. A display device, comprising the display module according to claim 1.

17. A preparation method for a display module, comprising:
providing a display substrate comprising a display area and a first bonding area and a second bonding area sequentially disposed on one side of the display area, a bonding pad being disposed on the second bonding area;
bonding an integrated circuit chip on the first bonding area, the integrated circuit chip comprising a first side edge on a side close to the bonding pad;
providing a flexible circuit board, which is provided with through holes;
bonding the flexible circuit board to the bonding pad of the second bonding area, the through holes exposing at least part of the first side edge;
coating a first protective layer on the first side edge exposed by the through holes.

18. The preparation method for a display module according to claim 17, wherein a through hole of the through holes comprises a first sidewall on a side close to the bonding pad, and the first protective layer is coated on the first side edge and the first sidewall simultaneously.

19. The preparation method for a display module according to claim 17, wherein
the integrated circuit chip further comprises edge portions located on other sides of the integrated circuit chip;
before the flexible circuit board is bonded to the bonding pad of the display substrate, a second protective layer is coated on the edge portions of other sides of the integrated circuit chip.
